(19) United States
(12) Patent Application Publication
(10) Pub. No.: US 2006/0037192 A1
(43) Pub. Date: Feb. 23, 2006

(54) Printed wiring board without traces on surface layers enabling PWB's without solder resist

(75) Inventors: Tero Kalevi Karkkainen, Halikko (FI); Kalle Salokannel, Salo (FI)

Correspondence Address: HARRINGTON & SMITH, LLP, 4 RESEARCH DRIVE, SHELTON, CT, 06484-6212, US

(73) Assignee: Nokia Corporation

(21) Appl. No.: 10/920,522

(22) Filed: Aug. 17, 2004

(51) Int. Cl. H05K 3/36

(52) U.S. Cl. 29/830; 29/831; 29/836

(57) ABSTRACT

A method of manufacturing a printed wiring board is provided that results in there being no signal lines on the surface layers of the printed wiring board. Additionally, no solder resist printing is required on the printed wiring board during manufacture. This results in a printed wiring board without solder resist and without any signal lines on the surface layers. The surface layers contain only component solder pads.

### TECHNICAL FIELD

This invention relates generally to printed wiring board (PWB) manufacturing and, more specifically, relates to PWB manufacturing without traces on surface layers enabling PWBs to be fabricated without solder resist.

### BACKGROUND

The trend in electronic equipment is towards greater compactness of design and lighter weight, combined with higher speed and digitization, leading to more advanced functions. The semiconductors and PWBs that make up this type of electronic equipment are therefore required to support ever-higher speeds and mounting densities.

The PWB is the foundation for virtually all electronics. The PWB is the platform upon which electronic components such as integrated circuit chips and discrete passive components are mounted. The PWB, also referred to as a printed circuit board (PCB), provides the physical structure for mounting and holding electronic components as well as the electrical interconnection between components. A PWB includes a non-conducting substrate (typically fiberglass with epoxy resin) upon which a conductive pattern or circuitry is formed. Copper is the most prevalent conductor, although nickel, silver, tin, tin-lead, and gold may also be used as etch-resists or top-level metal. There are three types of PWBs: single-sided, double-sided, and multilayer. Single-sided PWBs have a conductive pattern on one side only, double-sided boards have conductive patterns on both sides (top and bottom), and multilayer boards contain two or more double-sided PWBs that are bonded together. The conductive pathways or traces and other features are connected by plated through-holes, which are also used to mount and electrically connect components. PWBs may be rigid, flexible or flex-rigid.

A variety of processes have been used for forming the conductive pathways on the non-conductive substrate of PWBs. For example, a metal film such as copper can be applied to a non-conductive substrate such as one made of fiberglass, epoxy, and/or polyamide. In a common process, a sheet of the conductive metal is laminated to the non-conductive substrate and a photoresist is then coated on the metal sheet. The resulting PWB is then exposed to a pattern of light employing a light mask to reproduce the metal pathway pattern desired. This exposure is followed by photoresist development and then metal etching in the areas unprotected by the photoresist, in order to produce the desired circuit pattern. In the alternative, an etch resist can be directly printed such as by silk screen on the metal laminate sheet followed by curing and then metal etching. This multi-step process is time-consuming and relatively expensive.

Solder resist or solder mask is a permanent coating of a resin formulation, generally green in color, which encapsulates and protects all of the surface features of a PWB except the specific areas where it is required to form solder joints. The solder resist is applied to prevent wetting by molten solder of only desired areas during assembly, and also provides electrical insulation and protection against oxidation and corrosion.

As electronics packages continue to become smaller, the input/output pitch of these packages becomes denser. This causes challenges for applying solder resist during PWB manufacturing. As migration to finer-pitch chip-scale packages increases, such as 0.5 mm or finer, the application of PWB solder resist plays a larger role in the reliability of the assemblies. The process tolerances for applying solder resist to PWBs during manufacturing are not sufficient to meet the challenge caused by high density input/output electronic packages.

Currently this challenge is solved by modifying line widths on PWBs between the input/output pads, or by modifying the input/output pad shapes. However, these solutions cause reliability problems. There is therefore a need for a more accurate process for PWB manufacturing.

### SUMMARY OF THE PREFERRED EMBODIMENTS

The foregoing and other problems are overcome, and other advantages are realized, in accordance with the presently preferred embodiments of these teachings.

An embodiment of the present invention is the simplification of PWB manufacturing. This approach is enabled by the implementation of vertical high-density interconnection (VHDI) technology.

In the presently preferred non-limiting embodiment of this invention there are no signal lines on the surface layers of a PWB. Additionally, no solder resist printing is required on the PWB during manufacture. This results in a PWB without solder resist and without any signal lines on the surface layers. The surface layers contain only component solder lands.

A non-limiting embodiment of this invention provides a method for fabricating a PWB. The method for fabricating the PWB includes providing a dielectric substrate which includes multiple dielectric layers, the dielectric substrate having first and second surface layers, and forming on at least one of the surfaces a plurality of circuit attachment pads, where all interconnections of the PWB are located within the dielectric substrate, beneath the surface layers, to electrically interconnect the circuit attachment pads.

A further non-limiting embodiment of this invention relates to a PWB that is manufactured in accordance with the method for fabricating the PWB and a device having a PWB manufactured in accordance with the method for fabricating the PWB.

Advantages of this approach include a simplified PWB manufacturing process which results in decreased manufacturing costs, shorter delivery times, improved reliability and better yield due to a simplified manufacturing process and ensured quality control.

Additional advantages to this approach include higher packaging density on applications which results in the ability to miniaturize applications, improved electrical performance due to shorter signal lines in miniaturized products, as well as improved electrical performance and the possibility to employ higher clock frequencies.

### BRIEF DESCRIPTION OF THE DRAWINGS

The foregoing and other aspects of these teachings are made more evident in the following Detailed Description of the Preferred Embodiments, when read in conjunction with the attached Drawing Figures, wherein:

FIG. 1 is a top view of a conventional PWB with solder resist and traces on a surface layer;

FIG. 2 is a top view of a PWB with no solder resist and no traces on the surface layer in accordance with the present invention;

FIG. 3 is a enlarged cross sectional view of a conventional multilayer PWB with solder resist;

FIG. 4 is an enlarged view of a portion of the surface of FIG. 3 with solder resist and traces;

FIG. 5 is an enlarged cross sectional view of a PWB with no conductive traces and no solder resist material on the surface layers of the PWB in accordance with the present invention;

FIG. 6 is an enlarged view of a portion of the surface of FIG. 4 with no solder resist and no traces on the surface;

FIG. 7A-7B are enlarged cross sectional views of the method of fabricating a PWB according to the present invention; and

FIG. 8 is an enlarged cross-sectional view showing a component electrically connected to a circuit attachment pad of the PWB with no conductive traces and no solder resist material on the surface layers.

### DETAILED DESCRIPTION OF THE PREFERRED EMBODIMENTS

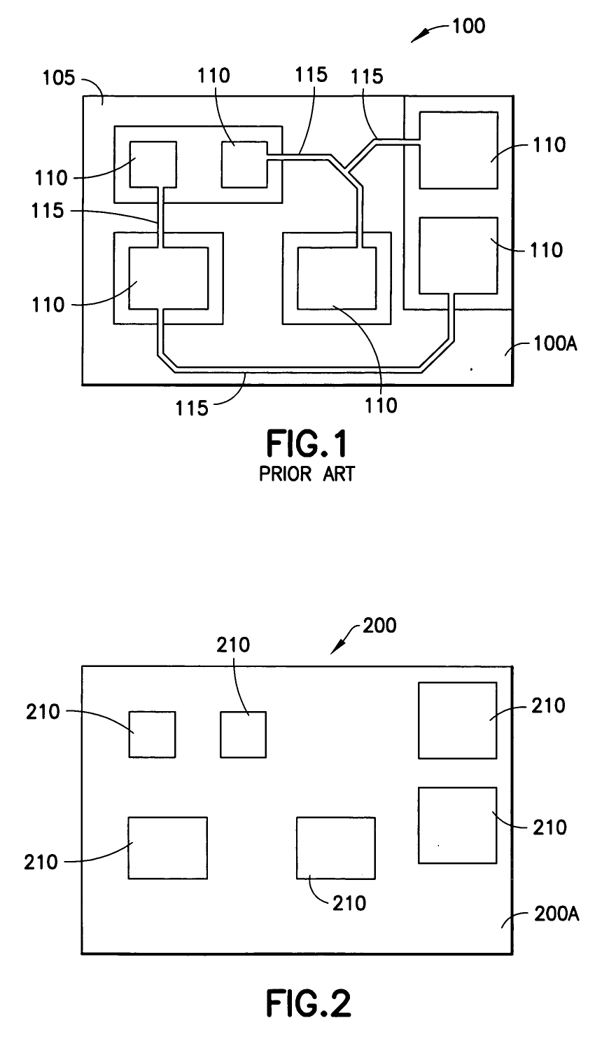

FIG. 1 shows a top view of a conventional PWB 100 having a top surface layer 100A with solder resist 105, solder joint pads 110, for components such as resistors, capacitors, diodes, integrated circuits, and the like, and interconnecting traces 115 on the surface layer 100A.

The purpose of solder resist 105 in conventional PWBs is to keep solder paste on a solder joint area during the soldering process of the various components. Solder paste is spread equally among visible metal areas. If any solder resist 105 is missing from the PWB, solder paste tends to spread among traces located on the surface layers causing unreliable interconnections.

FIG. 2 shows a PWB 200 according to an embodiment of this invention. This PWB 200 has no solder resist and no traces on the top (and preferably bottom) surface layer 200A. The only materials on the surface layer 200A are solder joint pads 210. That is, the surface layer 200A contain, only the component solder joint pads 210, herein referred to also as solder lands and component mounting pads. Beneficially, the surface layer 200A has no interconnecting traces between the solder joint pads 210, as in the conventional PWB 100 of FIG. 1. As such, it is also possible to eliminate the use of solder resist from the surface layer 200A of the PWB 200. Thus, further in accordance with an aspect of this invention, the reliability of electronics applications increases.

The interconnections between solder joint pads 210 are accommodated instead on the inner layers of the PWB 200. Connections to the inner layers are preferably made with vias, such as micro vias. Micro vias are generally defined as a formed blind and buried via that measure less than or equal to 0.15 mm, having pad diameters that measure less than or equal to 0.35 mm. Laser drilling is the most common technique used to form micro vias. Laser drilling employs a focused laser beam to form the hole. Conductive ink may also be used in micro via formation. Micro vias can also be formed mechanically, using piercing, punching, abrasive blasting, or simple drilling. Each process produces different micro via hole shapes.

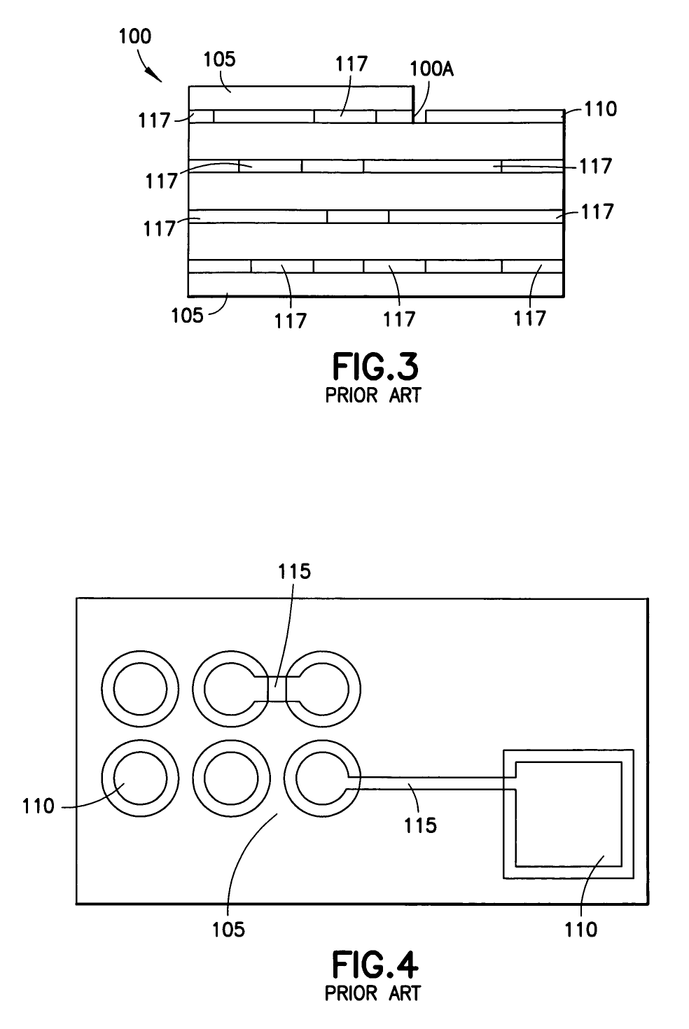

FIG. 3 shows a cross sectional view of the conventional multilayer PWB 100 with solder resist 105, solder joint pads 110, traces 115 on the surface layer 100A and buried trace interconnections 117. Such conventional multilayer PWBs are subjected to drilling and through-hole plating to create the top surface and buried interconnections 105, 117.

FIG. 4 is an enlarged view of a portion of the surface 100A of FIG. 3 showing solder joint pads 110, traces 115 on the surface layer and solder resist 105.

FIG. 5 shows a cross sectional view of the multilayer PWB 200 according to the presently preferred embodiment of this invention. The PWB 200 has the solder joint pads 210 on the surface layer 200A and possibly also on the bottom surface layer 200B. Electrically conductive traces 215 for interconnecting the leads of the components are contained within the PWB 200. In other embodiments of this invention, active and/or passive components can be embedded in the PWB 200. It is noted that the PWB has no solder resist and no signal lines on the surface layers 200A and 200B of the PWB 200 resulting in improved interconnection reliability. That is, the surface layers 200A, 200B contain only component solder pads 210, and are beneficially free of interconnecting traces and also solder resist.

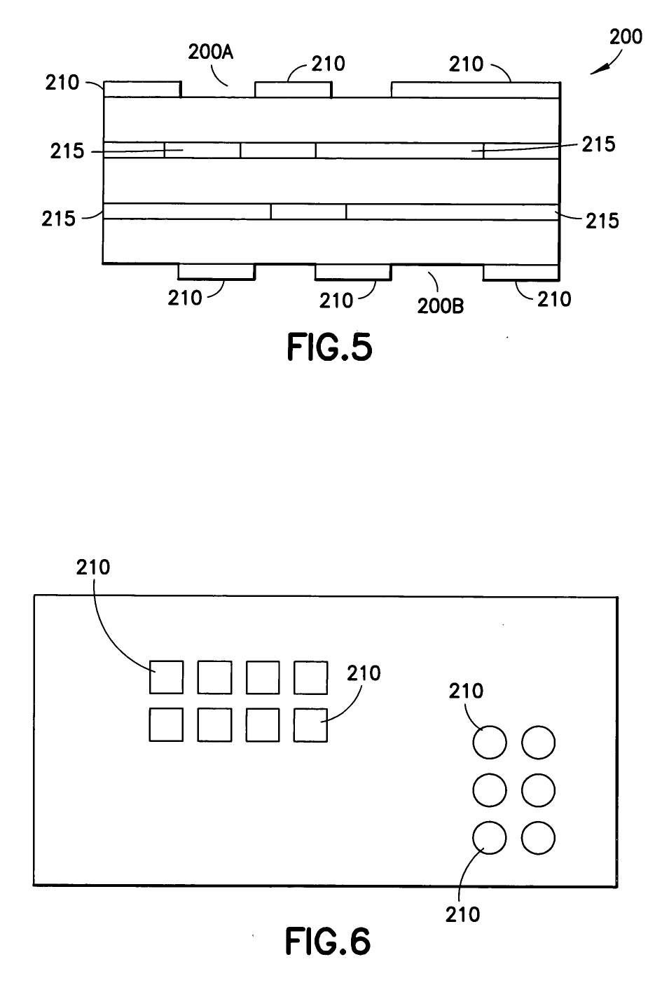

FIG. 6 shows an enlarged view of a portion of the surface of FIG. 5 showing various and non-limiting solder joint pad 210 geometries and placements.

A method according to a non-limiting embodiment of this invention preferably uses vertical high density interconnection technology. High density interconnects (HDI) are substrates or PWBs with a greater wiring density per unit area than conventional substrates or PWBs. HDI involves the sequential addition of a dielectric layer to form micro vias by metallizing one or both sides of a traditional PWB, which acts as a core. These micro vias are blind and traverse one or more layers in the stack, allowing for coincident placement of components. HDI uses blind and buried micro vias; which occupy only the layers that they traverse. HDI is also referred to as a “build-up” board, a “sequential build-up (SBU)” or “micro via technology.”

Other attributes of HDI include finer lines and spaces (<75 micron) and smaller vias (15 micron) and capture pads (400 micron) than employed in conventional technology, which are used to reduce size and weight and to enhance electrical performance.

Vertical high-density interconnection technology provides thru PWB vertical interconnects between any layers of a substrate. The end result is somewhat analogous to the thru-holes in conventional PWBs.

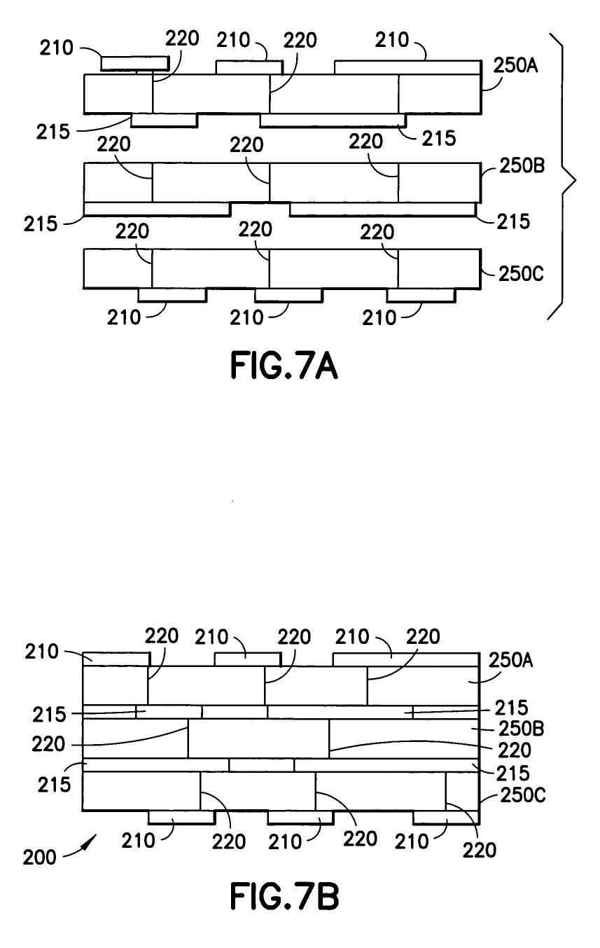

FIG. 7A-7B show a cross sectional view of the method of fabricating a PWB according to the non-limiting embodiment of this invention. Generally, the PWB may be fabricated using conventional PWB manufacturing methods. FIG. 7A shows three double sided PWBs 250A, 250B, 250C, collectively referred to as PWBs 250. The PWBs 250 have solder joint pads 210 on what will be the surface layers 200A, 200B, of the completed PWB 200. The PWBs 250 contain conductive traces and interconnects 215, as well as vias 220. FIG. 7B shows these double sided PWBs 250 bonded together to form the multilayer PWB 200 according to the present invention. The PWBs 250 may also contain embedded passive and/or active components if required by the application. The multilayer PWB 200 of the present invention may also include alternative layers of conductive and insulating material bonded together.

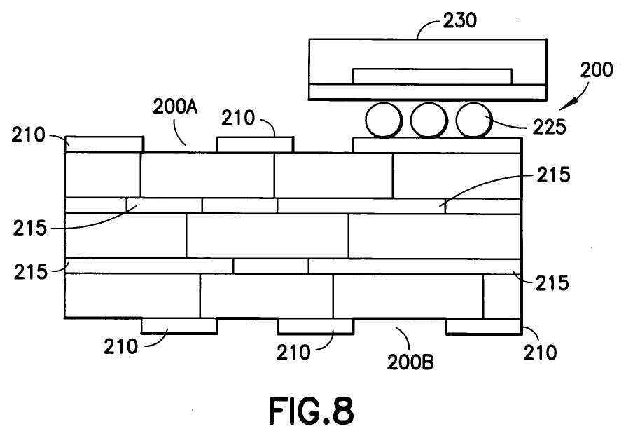

FIG. 8 shows a cross-sectional view of the multilayer PWB 200 according to the presently preferred embodiment of this invention. The PWB 200 has solder joint pads 210 on the surface layer. Also shown is a component 230 electrically connected to a solder joint pad 210 of the PWB 200 via solder balls 225. It is to be noted that the PWB 200 has no solder resist and no signal lines on the surface layer.

In accordance with preferred embodiments of this invention, the PWBs 250 are fabricated such that the top surface 200A, and also preferably the bottom surface 200B, are free of interconnecting traces 115, and instead contain only the solder joint pads 210. It thus becomes possible to not form the conventional solder resist layer 105 on the surface 200A, and 200B, and to thereby eliminate the problems inherent in the use of the solder resist layer(s) 105.

A PWB 200 in accordance with the preferred embodiments of this invention may be used for portable products such as: wireless communication devices, including cellular phones; image capture devices, including camcorders, digital cameras and film cameras equipped with electronic circuit boards; music storage and playback devices, including MP3 players and the like; personal digital assistants (PDAs); internet appliances; computers; and in products that combine the functionality of two or more such devices (e.g. a cellular phone containing a digital camera). This PWB 200 is well suited for use with fine-pitch IC packages. In general, a PWB 200 in accordance with the preferred embodiments of this invention can be used in any circuit boards, including those with high density requirements.

The foregoing description has provided by way of exemplary and non-limiting examples a full and informative description of the best method and apparatus presently contemplated by the inventors for carrying out the invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention.

What is claimed is:

1. A method to fabricate a printed wiring board comprising:
providing a dielectric substrate comprising multiple dielectric layers, said substrate having first and second surface layers; and
forming on at least one of said surface layers a plurality of circuit attachment pads;
where all interconnections of said printed wiring board are located beneath said at least one of said surface layers within the dielectric substrate to electrically interconnect said circuit attachment pads.

2. A method as in claim 1, wherein the interconnections comprise electrically conductive traces and at least one via.

3. A method as in claim 1, wherein the fabrication method uses a vertical high density interconnect process.

4. A method as in claim 1, wherein all interconnections in the printed wiring board between said pads are contained within the printed wiring board, and where a surface layer opposite said at least one surface layer is free of interconnections.

5. A method as in claim 1, wherein the dielectric layers contain at least one of a passive and an active component.

6. A method to fabricate a printed wiring board comprising:
providing a dielectric substrate comprising multiple dielectric layers; said substrate having first and second surface layers, and
forming on a top surface layer of said substrate a plurality of circuit attachment pads;
where all interconnections of said printed wiring board are located beneath the surface layers within the dielectric substrate to electrically interconnect said plurality of circuit attachment pads.

7. A method as in claim 6, where all interconnections in the printed wiring board between said pads are contained within the printed wiring board.

8. A printed wiring board comprising:
a dielectric substrate, said substrate having first and second surface layers, at least one of said surface layers comprising circuit attachment pads; and
a plurality of electrically conductive interconnections within said dielectric substrate;
wherein all of said interconnections are disposed beneath the surface layers and within the dielectric substrate.

9. A printed wiring board as in claim 8, wherein the printed wiring board comprises at least one via formed in the dielectric substrate.

10. A printed wiring board as in claim 8, wherein said circuit attachment pads are formed on both said first and second surface layers.

11. A printed wiring board comprising:
a dielectric substrate comprising multiple dielectric layers, said substrate having first and second surface layers, at least one of said surface layer comprising circuit attachment pads; and
a plurality of electrically conductive interconnections on said dielectric substrate;
wherein all of said interconnections are disposed beneath the surface layers; and
at least one electrical component electrically coupled to said circuit attachment pads.

12. A printed wiring board as in claim 11, wherein all interconnections in said printed wiring board between said pads are contained within the printed wiring board.

13. A printed wiring board as in claim 11, wherein the dielectric layers contain at least one of a passive and an active component.

14. A device comprising at least one printed wiring board, said printed wiring board comprising at least one surface layer comprising circuit attachment pads that are electrically coupled together through interconnections where all of said interconnections are located beneath the at least one surface layer of said printed wiring board.

15. A device as in claim 14, wherein said device comprises at least one of a wireless communication device, an image capture device, a music storage and playback device, a personal digital assistant, a computer and an internet appliance.

16. A printed wiring board comprising a top surface and a bottom surface wherein said top surface comprises a first set of component mounting pads, wherein all interconnections between said first set of component mounting pads are disposed beneath said top surface of said printed wiring board.

17. A printed wiring board as in claim 16, further comprising a second set of component mounting pads disposed on said bottom surface, and wherein all interconnections between said second set of component mounting pads, and between said second set of component mounting pads, and said first set of component mounting pads, are disposed beneath said top surface and said bottom surface.
